(19) United States
(12) Patent Application Publication
(10) Pub. No.: US 2023/0305081 A1
(43) Pub. Date: Sep. 28, 2023

(54) FUSE BLOW DETECTION CIRCUIT

(71) Applicant: Prime Planet Energy & Solutions, Inc., Tokyo (JP)

(72) Inventor: Masato NAKAYAMA, Akashi-shi (JP)

(21) Appl. No.: 18/186,217

(22) Filed: Mar. 20, 2023

(30) Foreign Application Priority Data
Mar. 22, 2022 (JP) 2022-045338

(51) Int. Cl. G01R 31/74; G01R 31/54

(52) U.S. Cl. CPC G01R 31/74; G01R 31/54

(57) ABSTRACT

A fuse blow detection circuit disclosed herein is provided in an output circuit in which a battery and a fuse are connected in series. The fuse blow detection circuit includes a detection line on which a detection resistance, a measurement switch, and a first resistance are connected in series, the detection line being connected to the output circuit in parallel, a second resistance connected to a connection point between the measurement switch and the first resistance on the detection line and connected to a connection point between the battery and the fuse in the output circuit, a first voltage measurement section that measures a battery voltage of the battery relative to a reference potential, and a second voltage measurement section that measures a detection voltage applied to the detection resistance relative to the reference potential.

### CROSS REFERENCE OF RELATED APPLICATION

The present application claims priority from Japanese Patent Application No. 2022-045338 filed on Mar. 22, 2022, which is incorporated by reference herein in its entirety.

### BACKGROUND

The present disclosure relates to a fuse blow detection circuit.

Japanese Laid-open Patent Publication No. 2008-86069 discloses a vehicular power supply device including a travel battery in which a plurality of battery modules are connected in series and a voltage detection circuit that detects voltages of the battery modules of the travel battery. In the travel battery, battery blocks at a positive side and at a negative side are connected in series via a fuse. The fuse and a first intermediate connection point between the battery blocks are connected to the voltage detection circuit via a reference connection line. In each of the battery blocks, the plurality of battery modules are connected in series at connection points. The connection points are connected to the voltage detection circuit via a detection switch. The detection switch is divided into a plurality of switch blocks. In the vehicular power supply device disclosed in Japanese Laid-open Patent Publication No. 2008-86069, either or both of breakage of the reference connection line and breakage of the fuse can be detected by switching on and off each of the switch blocks.

### SUMMARY

Incidentally, the present inventor desires to highly accurately detect a blow of a fuse in a circuit in which the fuse is provided.

A fuse blow detection circuit disclosed herein is provided in an output circuit in which a battery and a fuse are connected in series. The fuse blow detection circuit includes a detection line on which a detection resistance, a measurement switch, and a first resistance are connected in series, the detection line being connected to the output circuit in parallel, a second resistance connected to a connection point between the measurement switch and the first resistance on the detection line and connected to a connection point between the battery and the fuse in the output circuit, a first voltage measurement section that measures a battery voltage of the battery relative to a reference potential, and a second voltage measurement section that measures a detection voltage applied to the detection resistance relative to the reference potential. According to the fuse blow detection circuit, a blow of the fuse can be highly accurately detected.

The fuse blow detection circuit may further include a controller configured or programmed to determine whether the fuse is blown, based on the detection voltage measured by the second voltage measurement section when the measurement switch is in an on state.

The controller may be configured or programmed to determine whether the measurement switch has an open fault, based on the detection voltage when the measurement switch is in an on state.

The controller may be configured or programmed to execute processes of determining that the fuse is not blown when the detection voltage is a preset first voltage, determining that the fuse is blown when the detection voltage is a preset second voltage that is lower than the first voltage and determining that the measurement switch has an open fault when the detection voltage is a preset third voltage that is lower than the second voltage.

The second voltage measurement section may further measure the detection voltage when the measurement switch is in an off state. The controller may determine whether the measurement switch has a close fault, based on the detection voltage when the measurement switch is in an off state.

A resistance value of the first resistance may be higher than a resistance value of the second resistance.

A resistance value of the second resistance may be higher than a resistance value of the first resistance value.

### BRIEF DESCRIPTION OF THE DRAWINGS

FIG. 1 is a circuit diagram illustrating an output circuit.

FIG. 2 is a circuit diagram illustrating the output circuit in a state where a measurement switch is on and a fuse is not blown.

FIG. 3 is a circuit diagram illustrating the output circuit in a state where a measurement switch is on and a fuse is blown.

FIG. 4 is a flowchart illustrating processing executed in a controller.

### DETAILED DESCRIPTION

One embodiment of a technology disclosed herein will be described below. As a matter of course, the embodiment described herein is not intended to be particularly limiting the present disclosure. The present disclosure is not limited to the embodiment described herein, unless specifically stated otherwise. Members/portions that have the same effect will be denoted by the same sign as appropriate and the overlapping description will be omitted as appropriate.

### <Output Circuit 1>

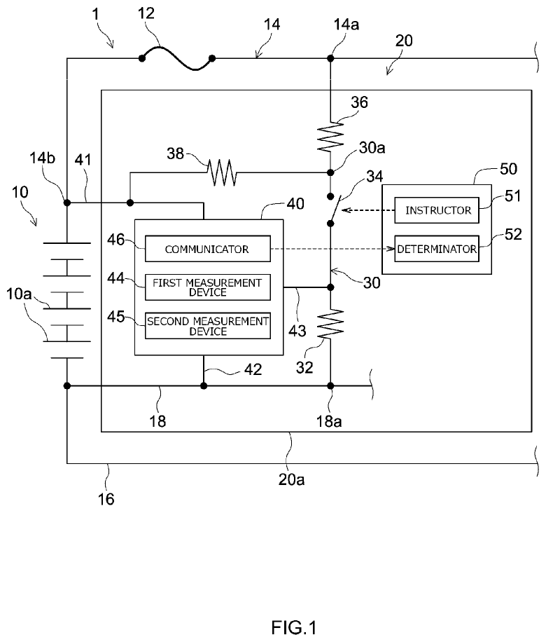

FIG. 1 is a circuit diagram illustrating an output circuit 1. As illustrated in FIG. 1, the output circuit 1 includes a battery 10, a fuse 12, and a fuse blow detection circuit 20. In this embodiment, as the battery 10, a battery module in which a plurality of secondary batteries 10a are connected in series is used. However, there is no particular limitation on a configuration of the battery 10. As the battery 10, for example, a single secondary battery 10a may be used, and the plurality of secondary batteries 10a may be used. The plurality of secondary batteries 10a are not limited to those connected in series, may be connected in parallel. The plurality of secondary batteries 10a may include secondary batteries 10a connected in series and secondary batteries 10a connected in parallel. As used herein, the term “secondary battery” refers to storage devices in general that can be repeatedly charged and discharged and is a concept including, in addition to so-called storage batteries (that is, chemical batteries), such as lithium-ion secondary batteries, nickel hydride batteries, nickel cadmium batteries, or the like, capacitors (that is, physical batteries), such as electric double layer capacitors or the like.

In the output circuit 1, the battery 10 and the fuse 12 are connected in series. The fuse 12 is provided on a positive electrode side connection line 14 connecting a positive electrode of the battery 10 and an unillustrated electrical device as an output destination. A negative electrode side connection line 16 connecting the battery 10 and the unillustrated electrical device as an output destination is connected to a negative electrode of the battery 10. The negative electrode side connection line 16 is connected to a reference line 18. The reference line 18 is connected to an unillustrated reference potential point that becomes a reference potential of a potential of the battery 10.

The fuse 12 protects the device connected to the battery 10 and the output circuit 1 from an overcurrent flowing into the device. The fuse 12 is configured to be blown when a current equal to or higher than a preset rating current flows. The fuse blow detection circuit 20 that detects a blow of the fuse 12 is provided in the output circuit 1.

### <Fuse Blow Detection Circuit 20>

The fuse blow detection circuit 20 detects whether the fuse 12 is blown at a preset timing. There is no particular limitation on a timing of detection of a fuse blow. For example, detection of a fuse blow can be performed before an electrical device is used. Detection of a fuse blow can be also performed when an abnormal condition occurs during use of the electrical device. For example, when an abnormal condition in which power is not supplied to the electrical device occurs, a cause of the abnormal condition can be specified by detecting a fuse blow. The fuse blow detection circuit 20 includes a detection line 30, a second resistance 38, a voltage measurement section 40, and a controller 50. The detection line 30 includes a detection resistance 32, a measurement switch 34, and a first resistance 36. In this embodiment, the above-described components of the fuse blow detection circuit 20 are provided on the same substrate 20a.

### <Detection Line 30>

On the detection line 30, the detection resistance 32, the measurement switch 34, and the first resistance 36 are connected in series in this order. The measurement switch 34 is provided between the recording head 32 and the first resistance 36. The measurement switch 34 is configured to be switchable between an on state and an off state by the controller 50 that will be described later. Although there is not particular limitation, as the measurement switch 34, for example, a semiconductor switch is used.

An end portion of the detection line 30 at a first resistance 36 side is connected to a connection point 14a of the positive electrode side connection line 14. An end portion of the detection line 30 at a detection resistance 32 side is connected to a connection point 18a of the reference line 18. Therefore, the detection line 30 is connected to the output circuit 1 in parallel via the reference line 18.

### <Second Resistance 38>

The second resistance 38 is connected to the detection line 30 and the output circuit 1. One end of the second resistance 38 is connected to a connection point 30a between the measurement switch 34 and the first resistance 36 on the detection line 30. The other end of the er end of the second resistance 38 is connected to a connection point 14b between the positive electrode of the battery 10 and the fuse 12 in the output circuit 1. In this embodiment, the other end of the second resistance 38 is connected to the connection point 14b via a first connection line 41 that will be described later.

### <Voltage Measurement Section 40>

The voltage measurement section 40 is connected to the output circuit 1 via the first connection line 41, a second connection line 42, and a third connection line 43. The first connection line 41 is connected between the positive electrode of the battery 10 and the fuse 12. The second connection line 42 is connected between the negative electrode of the battery 10 and the connection point 18a. The third connection line 43 is connected between the detection resistance 32 and the measurement switch 34.

The voltage measurement section 40 includes a first measurement device 44, a second measurement device 45, and a communicator 46. In this embodiment, the first measurement device 44 corresponds to a first voltage measurement section and the second measurement device 45 corresponds to a second voltage measurement section. The first measurement device 44 measures a battery voltage Vb of the battery 10 relative to the reference potential. The second measurement device 45 measures a detection voltage Vra applied to the detection resistance 32 relative to the reference potential. The first measurement device 44 and the second measurement device 45 may include a channel switching circuit, an A/D converter, or the like that are not illustrated. Although not illustrated, the first measurement device 44 is connected to positive electrodes and negative electrodes of the secondary batteries 10a via a plurality of wirings, and may be configured to measure a voltage of each of the secondary batteries 10a forming the battery 10. Analog voltage signals measured by the first measurement device 44 and the second measurement device 45 are analog-digital converted by the A/D converter. The converted digital voltage signal is transmitted to the communicator 46. The communicator 46 includes, for example, a communication interface. The communicator 46 is communicably connected with the controller 50 of the fuse blow detection circuit 20. The communicator 46 transmits the battery voltage Vb and the detection voltage Vra that have been digital converted to the controller 50 of the fuse blow detection circuit 20. There is no particular limitation on configurations of the first measurement section and the second measurement section. For example, each of the first voltage measurement section and the second voltage measurement section may be realized by a plurality of voltage measurement devices, and may be realized by a single voltage measurement device that can switch a circuit a voltage of which is measured.

### <Controller 50>

The controller 50 controls an on state and an off state of the measurement switch 34. The controller 50 determines a blow of the fuse 12, based on a voltage measured by the voltage measurement section 40. The controller 50 is, for example, a microcomputer. The controller 50 includes, for example, a communication interface, a CPU, a ROM, and a RAM.

The controller 50 includes an instructor 51 and a determinator 52. For example, each of the instructor 51 and the determinator 52 may be realized by a plurality of processors. The instructor 51 configured or programmed to instruct switching between an on state and an off state of the measurement switch 34. The determinator 52 configured or programmed to determine whether the fuse 12 is blown, based on a voltage (in this embodiment, the detection voltage Vra) received from the communicator 46 of the voltage measurement section 40.

Incidentally, when the measurement switch 34 is in an on state, a current flows in the detection resistance 32. From a viewpoint of suppressing power consumption of the battery 10, at a timing at which a blow of the fuse 12 is not detected, the measurement switch 34 is preferably in an off state. For example, in a case where the measurement switch 34 has been in an on state for a long time, the battery 10 is discharged, so that a charging amount of the battery 10 can be reduced.

The instructor 51 instructs switching between an on state and an off state of the measurement switch 34 at a preset timing of detecting a blow of the fuse 12. The instructor 51 is configured to be communicable with the measurement switch 34. An on state and an off state of the measurement switch 34 can be switched by transmitting a switching signal from the instructor 51 to the measurement switch 34. A timing of detecting a blow of the fuse 12 may be stored, for example, in a memory of the controller 50.

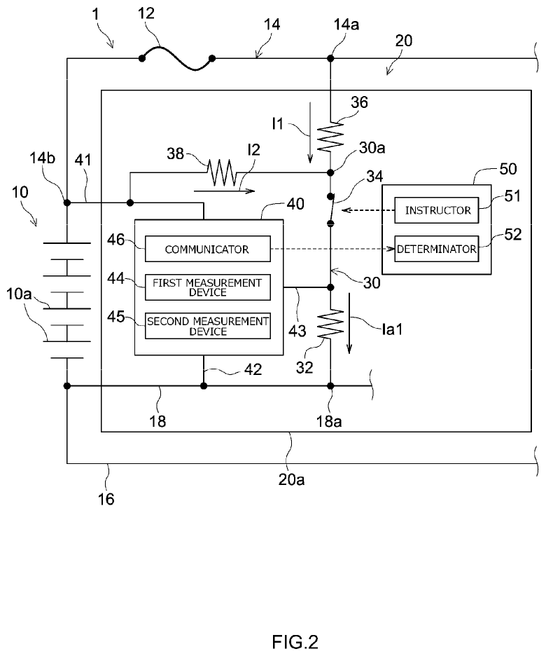

The determinator 52 of the controller 50 determines a blow of the fuse 12, based on the detection voltage Vra measured by the second measurement device 45 of the voltage measurement section 40 when the measurement switch 34 is in an on state. FIG. 2 is a circuit diagram illustrating the output circuit 1 in a state where the measurement switch 34 is on and the fuse 12 is not blown. In this embodiment, the first resistance 36 and the second resistance 38 have a same resistance value Rb. The detection resistance 32 has a resistance value Ra. As illustrated in FIG. 2, when the fuse 12 is not blown, voltages are applied to the first resistance 36, the second resistance 38, and the detection resistance 32 and currents I1, I2, and Ia1 flow in the first resistance 36, the second resistance 38, and the detection resistance 32, respectively.

Herein, the first resistance 36 and the second resistance 38 are connected to the detection resistance 32 in series in a state where the first resistance 36 and the second resistance 38 are connected in parallel. Therefore, a combined resistance of the detection resistance 32, the first resistance 36, and the second resistance 38 is Ra+(Rb/2). The detection voltage Vra applied to the detection resistance 32 is expressed by Expression 1 below.

Vra=Vb×Ra/(Ra+(Rb/2)) [Expression 1]

In this specification, the detection voltage Vra that is calculated when being applied to the detection resistance 32 in a state where the measurement switch 34 is on and the fuse 12 is not blown and is expressed by Expression 1 above is referred to as a “first voltage” as appropriate. A first voltage V1 is determined based on a resistance value of a resistance (in this embodiment, the detection resistance 32, the first resistance 36, and the second resistance 38) used for the fuse blow detection circuit 20 and the battery voltage Vb measured by the first measurement device 44 of the voltage measurement section 40.

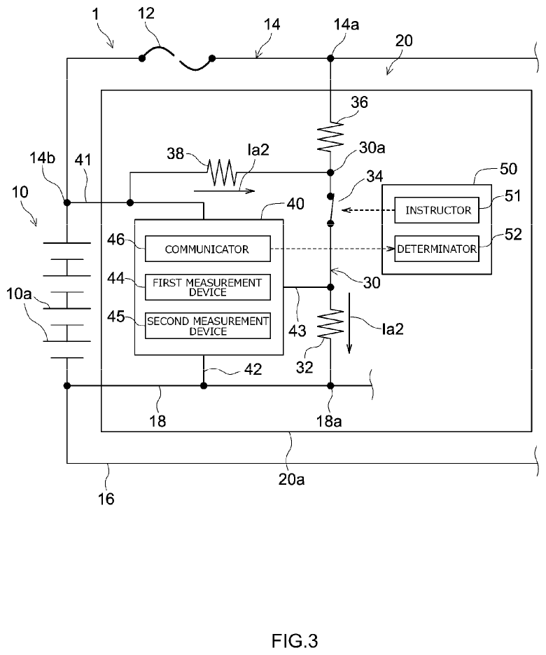

On the other hand, when the fuse 12 is blown, in the voltage measurement section 40, a value different from the detection voltage Vra expressed by Expression 1. FIG. 3 is a circuit diagram illustrating the output circuit 1 in a state where the measurement switch 34 is on and the fuse 12 is blown. As illustrated in FIG. 3, even when the fuse 12 is blown, voltages are applied to the second resistance 38 and the detection resistance 32 and the current Ia2 flows therein. However, when the fuse 12 is blown, an output to the first resistance 36 can be blocked by an unillustrated output blocking device provided between an output end of the fuse 12 and an output destination. No voltage is applied to the first resistance 36 and no current flows therein.

Herein, a combined resistance of the detection resistance 32 and the second resistance 38 is Ra+Rb. The detection voltage Vra applied to the detection resistance 32 is expressed by the Expression 2 below.

Vra=Vb×Ra/(Ra+Rb) [Expression 2]

In this specification, the detection voltage Vra that is calculated when being applied to the detection resistance 32 in a state where the measurement switch 34 is on and the fuse 12 is blown and is expressed by Expression 2 above is referred to as a “second voltage” as appropriate. A second voltage V2 is a voltage lower than the first voltage V1. Similar to the first voltage V1, the second voltage V2 is determined based on the resistance value of the resistance used for the fuse blow detection circuit 20 and the battery voltage Vb measured by the first measurement device 44 of the voltage measurement section 40. For example, in this embodiment, the first voltage is expressed by Vb×Ra/(Ra+(Rb/2)) (see Expression 1). The second voltage V2 is expressed by Vb×Ra/(Ra+Rb) (see Expression 2). Therefore, a value of the second voltage V2 is lower than a value of the first voltage V1.

Resistance values of the detection resistance 32, the first resistance 36, and the second resistance 38 are preset. The battery voltage Vb of the battery 10 is a value measured by the voltage measurement section 40 and is not affected by whether the fuse 12 is blown. Accordingly, the determinator 52 of the controller 50 can determine a blow of the fuse 12, based on the detection voltage Vra measured by the voltage measurement section 40 when the measurement switch 34 is in an on state. For example, when the detection voltage Vra applied to the detection resistance 32 is the first voltage V1 expressed by Expression 1, it is determined that the fuse 12 is not blown and, when the detection voltage Vra is the second voltage V2 expressed by Expression 2, it is determined that the fuse 12 is blown.

Incidentally, there is a probability that, in the measurement switch 34 provided on the detection line 30, a fault occurs, for example, due to degradation over time or the like. In the fuse blow detection circuit 20 described above, not only whether the fuse 12 is blown is detected, but also a fault of the measurement switch 34 can be detected. Examples of a fault of the measurement switch 34 include, for example, an open fault and a close fault. The open fault is a fault in which the measurement switch 34 is disconnected at all times. In the open fault of the measurement switch 34, for example, even when the instructor 51 of the controller 50 instructs switching the measurement switch 34 to an on state, an off state is maintained. The close fault is a fault in which the measurement switch 34 is fixed at all times. In the close fault of the measurement switch 34, for example, even when the instructor 51 of the controller 50 instructs switching the measurement switch 34 to an off state, an on state is maintained.

In the fuse blow detection circuit 20, the controller 50 can determine whether the measurement switch 34 has an open fault, based on the detection voltage Vra when the measurement switch 34 is in an on state.

In a case where the measurement switch 34 has an open fault, as described above, even when the instructor 51 instructs switching the measurement switch 34 to an on state, an off state is maintained. In this case, voltages are applied to the first resistance 36 and the second resistance 38, and currents flow in the first resistance 36 and the second resistance 38. No voltage is applied to the detection resistance 32 and no current flows therein. Since no voltage is applied to the detection resistance 32, a measurement value of the detection voltage Vra in the voltage measurement section 40 can be zero. As described above, in a state where an instruction of switching the measurement switch 34 to an on state has been given, it is determined by detecting that detection voltage Vra is zero that the measurement switch 34 has an open fault. In this specification, the detection voltage Vra that can be measured in a state where the measurement switch 34 is off is also referred to as a “third voltage” as appropriate.

In the fuse blow detection circuit 20, whether the measurement switch 34 has a close fault can be determined. In this embodiment, the voltage measurement section 40 further measures the detection voltage Vra when the measurement switch 34 is in an off state. The controller 50 determines whether the measurement switch 34 has a close fault, based on the detection voltage Vra when the measurement switch is in an off state.

In a case where the measurement switch 34 has a close fault, as described above, even when the instructor 51 instructs switching the measurement switch 34 to an off state, an on state is maintained. In this case, voltages are applied to the first resistance 36, the second resistance 38, and the detection resistance 32, and currents flow therein. Some other value than zero is indicated as the measurement value of the detection voltage Vra in the voltage measurement section 40. In other words, the detection voltage Vra can be some other voltage than the third voltage. As described above, in a state where an instruction of switching the measurement switch 34 to an off state has been given, when the detection voltage Vra is not zero, it is determined that the measurement switch 34 has a close fault.

Processing executed in the controller 50 will be described below using an example, but it is not intended to limit the present disclosure to the example.

A circuit configuration in this example is similar to the output circuit 1 and the fuse blow detection circuit 20 described above. The battery voltage Vb of the battery 10 is 48 V. The resistance value Ra of the detection resistance 32 is 4.7 kΩ. The resistance value Rb of the first resistance 36 is 200 kΩ. The resistance value Rb of the second resistance 38 is 200 kΩ.

The detection resistance 32, the first resistance 36, and the second resistance 38 can be set based on a voltage measurement range of the voltage measurement section 40 and a possible maximum voltage of the battery voltage Vb. The resistance value Ra of the detection resistance 32 with respect to a resistance value R12+Ra of a combined resistance of the first resistance 36, the second resistance 38 and the detection resistance 32 can be set to an upper limit value Vm or less of the voltage measurement range of the second measurement device 45 with respect to a maximum value of the battery voltage Vb. In other words, a resistance that is used can be set so as to satisfy Ra/(R12+Ra) Vm/Vb.

Based on Expression 1 described above, in a state where the measurement switch 34 is on and the fuse 12 is not blown, the detection voltage Vra (the first voltage V1) measured by the second measurement device 45 is calculated to be 2.15 V. Based on Expression 2 described above, in a state where the measurement switch 34 is on and the fuse 12 is blown, the detection voltage Vra (the second voltage V2) measured by the second measurement device 45 is calculated to be 1.1 V. The controller 50 can be configured or programmed to calculate the first voltage V1 and the second voltage V2, based on the battery voltage Vb measured by the first measurement device 44.

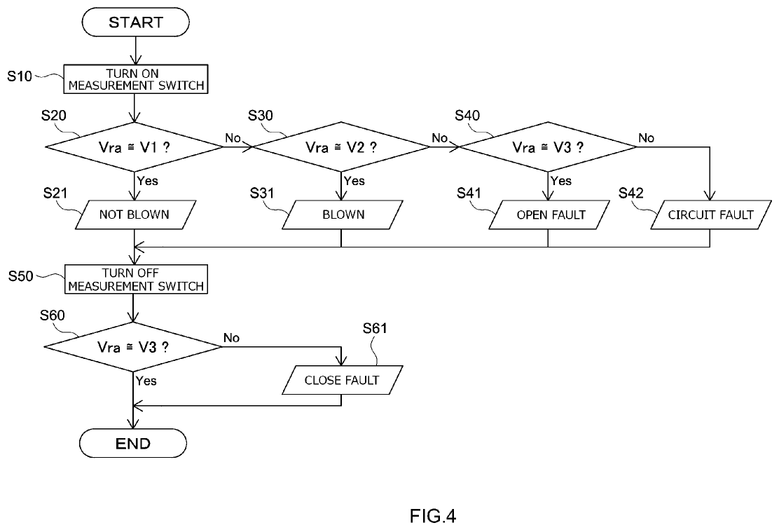

FIG. 4 is a flowchart illustrating processing executed in the controller 50. The processing starts at a preset timing of detecting a blow of the fuse 12.

In Step S10 of FIG. 4, the instructor 51 of the controller 50 executes processing of switching the measurement switch 34 from an off state to an on state. When the measurement switch 34 is switched to an on state, the instructor 51 further instructs the voltage measurement section 40 to measure the battery voltage Vb and the detection voltage Vra. The first measurement device 44 of the voltage measurement section 40 measures the battery voltage Vb. Herein, as described above, the battery voltage Vb is 48 V. The second measurement device 45 of the voltage measurement section 40 measures the detection voltage Vra. The battery voltage Vb and the detection voltage Vra that have been measured are transmitted to the determinator 52 of the controller 50 via the communicator 46. Subsequently, the process proceeds to Step S20.

In Step S20 of FIG. 4, in the controller 50, processing of determining, when the detection voltage Vra is the first voltage V1 (herein, 2.15 V), that the fuse 12 is not blown is executed. When the received detection voltage Vra is the first voltage V1, the determinator 52 determines Yes in determination of Step S20 and the process proceeds to Step S21. In the above-described processing, for the first voltage V1, a numerical value with a predetermined allowance can be set in consideration of a measurement error. When a difference between the detection voltage Vra and the first voltage V1 is within a predetermined range (there is no particular limitation thereon but, for example, within 0.05 V), the numerical value may be set such that it is determined that “the detection voltage Vra is the first voltage V1.” For example, “a case where the detection voltage is the first voltage V1” includes a case where a difference between the detection voltage and the first voltage is within a predetermined difference. Hereinafter, for the second voltage and the third voltage, numerical values with a predetermined allowance can be set in a similar manner. “A case where the detection voltage is the second voltage” includes a case where a difference between the detection voltage and the second voltage is within a predetermined difference. “A case where the detection voltage is the third voltage” includes a case where a difference between the detection voltage and the third voltage is within a predetermined difference.

In Step S21, it is determined that the fuse 12 is not blown, this result is output to a preset output destination (for example, a user terminal of the user who owns a device in which the output circuit 1 is provided). In Step S20, when the detection voltage Vra is not the first voltage V1, No is determined in Step S20 and the process proceeds to Step S30.

In Step S30 of FIG. 4, in the controller 50, processing of determining, when the detection voltage Vra is the second voltage V2 (herein, 1.1 V), that the fuse 12 is blown is executed. When the received detection voltage Vra is the second voltage V2, the determinator 52 determines Yes in Step S30 and the process proceeds to Step S31. In Step S31, it is determined that the fuse 12 is blown and this result is output to the preset output destination. In Step S30, when the detection voltage Vra is not the second voltage V2, the determinator 52 determines No in Step S30 and the process proceeds to Step S40.

In Step S40 of FIG. 4, in the controller 50, processing of determining, when the detection voltage Vra is the third voltage V3 (herein, 0 V), that the measurement switch 34 has an open fault is executed. When the received detection voltage Vra is the third voltage V3, the determinator 52 determines Yes in Step S40 and the process proceeds to Step S41. In Step S41, it is determined that the measurement switch 34 has an open fault, and this result is output to the preset output destination. In Step S40, when the detection voltage Vra is not the third voltage V3, the determinator 52 determines No in Step S40 and the process proceeds to Step S42. In Step S42, it is determined that there is a probability that a circuit (for example, the fuse blow detection circuit 20) included in the output circuit 1 has a portion that has a fault, and this result is output to the preset output destination.

In any one of Steps S21, S31, S41, and S42 is terminated, subsequently, the process proceeds to Step S50.

In Step S50 of FIG. 4, the instructor 51 of the controller 50 executes processing of switching the measurement switch 34 from an on state to an off state. When the measurement switch 34 is switched to an off state, similar to Step S10, the instructor 51 instructs the voltage measurement section 40 to measure the battery voltage Vb and the detection voltage Vra. The battery voltage Vb and the detection voltage Vra that have been measured are transmitted to the determinator 52 of the controller 50 via the communicator 46. Subsequently, the process proceeds to Step S60.

In Step S60 of FIG. 4, in the controller 50, processing of determining, when the detection voltage Vra is not the third voltage V3 (herein, 0 V), that the measurement switch 34 has a close fault is executed. When the received detection voltage Vra is not the third voltage V3, the determinator 52 determines No in Step S60 and the process proceeds to Step S61. In Step S61, it is determined that the measurement switch 34 has a close fault, and this result is output to the preset output destination. In Step S60, when the detection voltage Vra is the third voltage V3, the determinator 52 determines Yes in Step S60, and processing of detecting a blow of the fuse is terminated.

As described above, the fuse blow detection circuit 20 includes the detection line 30 on which the detection resistance 32, the measurement switch 34, and the first resistance 36 are connected in series, the detection line 30 being connected to the output circuit 1 in parallel, the second resistance 38 connected to the connection point 30a between the measurement switch 34 and the first resistance 36 on the detection line 30 and the connection point 14b between the battery 10 and the fuse 12 in the output circuit 1, the voltage measurement section 40 that measures the battery voltage Vb of the battery 10 relative to the reference potential and the detection voltage Vra applied to the detection resistance 32 relative to the reference potential, and the controller 50 that determines a blow of the fuse 12, based on the detection voltage Vra measured by the voltage measurement section 40 when the measurement switch 34 is in an on state. With the above-described configuration, a value of the detection voltage Vra differs between a case where the fuse 12 is blown and a case where the fuse 12 is not blown. By measuring the detection voltage Vra, it is possible to determine whether the fuse 12 is blown. Moreover, the second resistance 38 connected between the measurement switch 34 and the first resistance 36 and connected to an input end of the fuse 12 is provided. Thus, the value of the detection voltage Vra differs between a case where the fuse 12 is blown (in this example, 1.1 V) and a case where the measurement switch 34 has an open fault (in this example, 0 V). As a result, a blow of the fuse 12 and an open fault of the measurement switch 34 can be distinguished from each other.

As described above, the above-described components of the fuse blow detection circuit 20 are provided on the same substrate 20a. For example, a connection line of the second resistance 38 and the first connection line 41 connecting the voltage measurement section 40 to the output circuit 1 can be made common. Thus, the above-described circuit configuration can be realized by disposing each of the components on the substrate 20a. For example, it is not required to connect a wiring or a device used for detecting states of the fuse 12 and the measurement switch 34 from outside of the substrate 20a. The fuse blow detection circuit 20 can be configured by a simple configuration provided on the 20a.

In the above-described embodiment, the first resistance 36 and the second resistance 38 have the same resistance value Rb, but the resistance values of the first resistance 36 and the second resistance 38 are not limited thereto. The resistance values of the first resistance 36 and the second resistance 38 may be arbitrarily set.

For example, as in the above-described embodiment, when the resistance values of the first resistance 36 and the second resistance 38 are about the same, the detection voltage Vra (the second voltage V2: 1.1 V) when the fuse 12 is blown is about a half of the detection voltage Vra (the first voltage V1: 2.15 V) at a normal time at which the fuse 12 is not blown. When the measurement switch 34 has an open fault, the detection voltage Vra (the third voltage V3) is 0V. Therefore, the above-described voltage values are clearly different, and each state can be easily determined. From this viewpoint, a ratio of the resistance value of the second resistance 38 to the resistance value of the first resistance 36 can be set to, for example, 0.9 to 1.1.

Moreover, the larger an amount by which the resistance value of the second resistance 38 is higher than the resistance value of the first resistance 36 is, the lower the detection voltage Vra (the second voltage V2) when the fuse 12 is blown becomes as compared to the detection voltage Vra (the first voltage V1) at a normal time at which the fuse 12 is not blown. In other words, a difference between the first voltage V1 and the second voltage V2 increases. Thus, whether the fuse 12 is blown can be more easily detected.

On the other hand, the larger an amount by which the resistance value of the first resistance 36 is higher than the resistance value of the second resistance 38 is, the higher the detection voltage Vra (the second voltage V2) when the fuse 12 is blown becomes as compared to the detection voltage Vra (the first voltage V1) at a normal time at which the fuse 12 is not blown. Therefore, a difference between the second voltage V2 and the third voltage V3 increases. As a result, when the circuit has a fault, a cause of the fault of the circuit, that is, whether the fuse 12 is blown or the measurement switch 34 has an open fault, can be easily detected. As described above, the resistance values of the first resistance 36 and the second resistance 38 may be set in accordance with the configuration of the output circuit 1 and a purpose of providing the fuse blow detection circuit 20.

A technology disclosed herein has been described above in various manners. The embodiment or the like disclosed herein shall not limit the present disclosure, unless specifically stated otherwise. Various changes can be made to the fuse blow detection circuit disclosed herein, and each of components and processes described herein can be omitted as appropriate or can be combined with another one or other ones of the components and the processes as appropriate, unless a particular problem occurs.

What is claimed is:

1. A fuse blow detection circuit provided in an output circuit in which a battery and a fuse are connected in series, the fuse blow detection circuit comprising:
a detection line on which a detection resistance, a measurement switch, and a first resistance are connected in series, the detection line being connected to the output circuit in parallel;
a second resistance connected to a connection point between the measurement switch and the first resistance on the detection line and connected to a connection point between the battery and the fuse in the output circuit;
a first voltage measurement section that measures a battery voltage of the battery relative to a reference potential; and
a second voltage measurement section that measures a detection voltage applied to the detection resistance relative to the reference potential.

2. The fuse blow detection circuit according to claim 1, further comprising:
a controller configured or programmed to determine whether the fuse is blown, based on the detection voltage measured by the second voltage measurement section when the measurement switch is in an on state.

3. The fuse blow detection circuit according to claim 2,
wherein
the controller is configured or programmed to determine whether the measurement switch has an open fault, based on the detection voltage when the measurement switch is in an on state.

4. The fuse blow detection circuit according to claim 2,
wherein
the controller configured or programmed to execute processes of
determining that the fuse is not blown when the detection voltage is a preset first voltage,
determining that the fuse is blown when the detection voltage is a preset second voltage that is lower than the first voltage and
determining that the measurement switch has an open fault when the detection voltage is a preset third voltage that is lower than the second voltage.

5. The fuse blow detection circuit according to claim 2,
wherein
the second voltage measurement section further measures the detection voltage when the measurement switch is in an off state, and
the controller determines whether the measurement switch has a close fault, based on the detection voltage when the measurement switch is in an off state.

6. The fuse blow detection circuit according to claim 2,
wherein
a resistance value of the first resistance is higher than a resistance value of the second resistance.

7. The fuse blow detection circuit according to claim 2,
wherein
a resistance value of the second resistance is higher than a resistance value of the first resistance value.
